(19) United States
(12) Patent Application Publication
(10) Pub. No.: US 2026/0026262 A1
(43) Pub. Date: Jan. 22, 2026

(54) GEOTHERMAL THERMOELECTRIC POWER GENERATION MODULE AND GEOTHERMAL THERMOELECTRIC POWER GENERATOR

(71) Applicant: Shenzhen University, Shenzhen (CN)

(72) Inventors: Xiting LONG, Shenzhen (CN); Heping XIE, Shenzhen (CN); Licheng SUN, Shenzhen (CN); Tianyi GAO, Shenzhen (CN); Entong XIA, Shenzhen (CN); Shuheng LI, Shenzhen (CN); Jun WANG, Shenzhen (CN)

(21) Appl. No.: 19/340,754

(22) Filed: Sep. 25, 2025

Related U.S. Application Data
(63) Continuation of application No. PCT/CN2024/100273, filed on Jun. 20, 2024.

(30) Foreign Application Priority Data
Jul. 3, 2023 (CN) 202310807512.8

(51) Int. Cl. H10N 10/17; F24T 50/00

(52) U.S. Cl. CPC H10N 10/17; F24T 50/00

(57) ABSTRACT

The invention relates to the technical field of geothermal power generation, and particularly to a geothermal thermoelectric power generation module and a geothermal thermoelectric power generator. The geothermal thermoelectric power generation module comprises: a fixing clamp; a plurality of hot heat exchangers and a plurality of cold heat exchangers are arranged in the fixing clamp, the hot heat exchangers and the cold heat exchangers are oppositely arranged, a plurality of thermoelectric modules are arranged between the hot heat exchangers and the cold heat exchangers, and two ends of the hot heat exchanger are respectively provided with a hot water input interface and a hot water output interface; and two ends of the cold heat exchanger are respectively provided with a cold water input interface and a cold water output interface, and the thermoelectric module is connected with a wire and outputs electric energy to the outside.

### CROSS-REFERENCE TO RELATED APPLICATIONS

This application is a continuation of International Patent Application No. PCT/CN2024/100273 with a filing date of Jun. 20, 2024, designating the United States, now pending, and further claims priority to Chinese Patent Application No. 202310807512.8 with a filing date of Jul. 3, 2023. The content of the aforementioned applications, including any intervening amendments thereto, are incorporated herein by reference.

### TECHNICAL FIELD

The present invention relates to the technical field of geothermal power generation, and particularly to a geothermal thermoelectric power generation module and a geothermal thermoelectric power generator.

### BACKGROUND OF THE PRESENT INVENTION

The development and utilization of geothermal energy serving as one of five non-carbon-based energy sources is of great significance for establishing a “clean, low-carbon, safe and efficient” energy system. Besides direct utilization, geothermal power generation is an inevitable trend to achieve the energy development and large-scale utilization of geothermal resources. However, a total installed capacity of geothermal power generation in China is not as good as an installed capacity of wind power, photovoltaic power and hydropower.

The fundamental problem lies in the backwardness of geothermal power generation technology and equipment level. At present, geothermal power plants (flash distillation, ORC, etc.) mostly adopt a steam power cycle, that is, high-temperature gas drives a turbomachinery to rotate, thereby driving a generator to generate electricity. Thermoelectric power generation technology based on a Seebeck effect may break through the limitation of traditional power generation system from thermal energy to mechanical energy and then to electric energy, so as to achieve direct conversion from heat to electricity. The whole process is simple, without moving parts, and there are a higher reliability and a longer running life, thereby providing a new idea for geothermal power generation. However, at present, a geothermal thermoelectric power generator generally has a small power generation scale, thereby being difficult to be popularized and applied on a large scale.

### SUMMARY OF THE PRESENT INVENTION

An objective of the present invention is to provide a geothermal thermoelectric power generation module aiming at the defects in the prior art, and the geothermal thermoelectric power generation module may be flexibly assembled to increase or reduce a power generation scale, thereby facilitating popularization and application.

Another objective of the present invention is to provide a geothermal thermoelectric power generator, and the geothermal thermoelectric power generator is provided with the geothermal thermoelectric power generation module above, which can achieve modular assembly, improve the power generation scale, and facilitate use.

A geothermal thermoelectric power generation module comprises: a fixing clamp, wherein a plurality of hot heat exchangers and a plurality of cold heat exchangers are arranged in the fixing clamp, the hot heat exchangers and the cold heat exchangers are oppositely arranged, a plurality of thermoelectric modules are arranged between the hot heat exchangers and the cold heat exchangers, and two ends of the hot heat exchanger are respectively provided with a hot water input interface and a hot water output interface; and two ends of the cold heat exchanger are respectively provided with a cold water input interface and a cold water output interface, and the thermoelectric module is connected with a wire and outputs electric energy to the outside.

Further, a number of the cold heat exchangers is N, and one hot heat exchanger is arranged between two adjacent cold heat exchangers; and N is a natural number greater than 1.

Further, a plurality of accommodating spaces for accommodating the thermoelectric modules are formed between all the cold heat exchangers and the hot heat exchangers, the accommodating space is provided with a main-sequencing thermoelectric module group or a secondary-sequencing thermoelectric module group, and the main-sequencing thermoelectric module group and the secondary-sequencing thermoelectric module group are staggered; and electrode directions of the thermoelectric modules in the main-sequencing thermoelectric module group and the secondary-sequencing thermoelectric module group are opposite;
all the thermoelectric modules in the main-sequencing thermoelectric module group are connected in series through a wire to form a main primary thermoelectric module group, and all the main primary thermoelectric module groups are connected in parallel to form a main intermediate thermoelectric module group;
all the thermoelectric modules in the secondary-sequencing thermoelectric module group are connected in series through a wire to form a secondary primary thermoelectric module group, and all the secondary primary thermoelectric module groups are connected in parallel to form a secondary intermediate thermoelectric module group; and
the main intermediate thermoelectric module group and the secondary intermediate thermoelectric module group are connected in series.

Further, a fixing bracket for fixing the thermoelectric module is arranged between the hot heat exchanger and the cold heat exchanger, the thermoelectric module is fixed on the fixing bracket, and two sides of the thermoelectric module are respectively provided with a flexible heat-conducting silicone sheet.

Further, the fixing clamp comprises two clamping plates, a clamping space is formed between the two clamping plates, the clamping plate is provided with a plurality of connecting holes, and the two clamping plates are connected by connecting pieces penetrating through the connecting holes; and the connecting hole is located in a center position of the thermoelectric module in a length direction.

Further, the hot water input interface of the hot heat exchanger is located on the same side as the cold water output interface of the cold heat exchanger, the hot water output interface of the hot heat exchanger is located on the same side as the cold water input interface of the cold heat exchanger, and a hot water flow direction of the hot heat exchanger is opposite to a cold water flow direction of the cold heat exchanger.

Further, the hot heat exchanger and the cold heat exchanger are both a heat exchanger, a side surface of the heat exchanger connected with the thermoelectric module is provided with two limiting protrusions arranged in parallel, and an accommodating space matched with the fixing bracket is formed between the limiting protrusions.

Further, a middle part of a side surface of the clamping plate is provided with a boss, and when the clamping plate and the heat exchanger are clamped, the boss is inserted into an accommodating space between two limiting protrusions.

Further, the heat exchanger comprises a bottom shell and an end cover, two sides of the bottom shell are respectively provided with an inlet and an outlet, and the inlet and the outlet are respectively located at a lower end and an upper end of the bottom shell; and a middle part of the bottom shell is provided with a plurality of reinforcing ribs, and the reinforcing ribs divide an internal space of the heat exchanger into a plurality of channels.

Further, side plates on the two sides of the bottom shell are obliquely arranged, so that a water pressure difference between two sides of the channel is equal or within a predetermined range.

Preferably, an angle of inclination of the side plate is 10 degrees to 40 degrees.

Further, a width of the channel is gradually increased from the outside to the inside.

Further, an upper edge of the clamping plate is provided with a threaded hole.

Preferably, fluid turns are all designed with a transition fillet.

A geothermal thermoelectric power generator comprises a plurality of geothermal thermoelectric power generation modules above, and further comprises a hot water supply system and a cold water supply system, wherein the cold water supply system is connected with the cold heat exchanger, and the hot water supply system is connected with the hot heat exchanger.

The present invention has the beneficial effects that: according to the present invention, the thermoelectric power generation module is formed by arranging the thermoelectric modules between the cold heat exchangers and the hot heat exchangers, the thermoelectric power generation module has an expandability, and a plurality of thermoelectric power generation modules can be arranged according to needs to increase power generation power, thereby facilitating use.

### DESCRIPTION OF THE DRAWINGS

FIG. 1 is a schematic structural diagram of the embodiment.

FIG. 2 is an exploded schematic diagram of FIG. 1.

FIG. 3 is a schematic diagram of a clamping plate.

FIG. 4 is an exploded schematic diagram of a heat exchanger.

FIG. 5 is a schematic diagram of a sectional structure of the heat exchanger.

FIG. 6 is a schematic diagram of electrical connection of thermoelectric modules in a thermoelectric power generation module.

### REFERENCE NUMERALS IN THE DRAWINGS

1—clamping plate; 2—heat exchanger; 3—thermoelectric module; 4—fixing bracket; 5—heat-conducting silicone sheet; 6—connecting piece; 12—boss; 13—connecting hole; 211—end cover; 212—bottom shell; 213—limiting protrusion; 22—interface; 214—reinforcing rib; and 215—fillet.

### DETAILED DESCRIPTION OF PREFERRED EMBODIMENTS

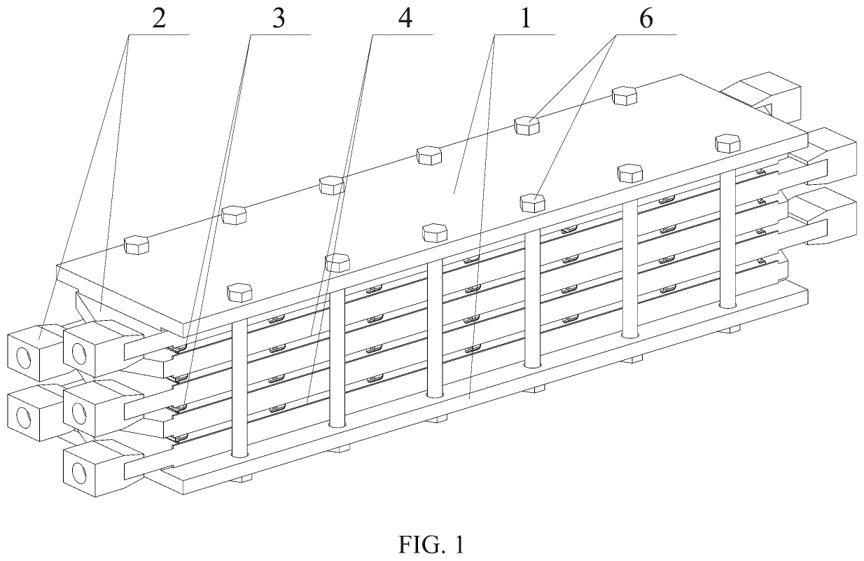

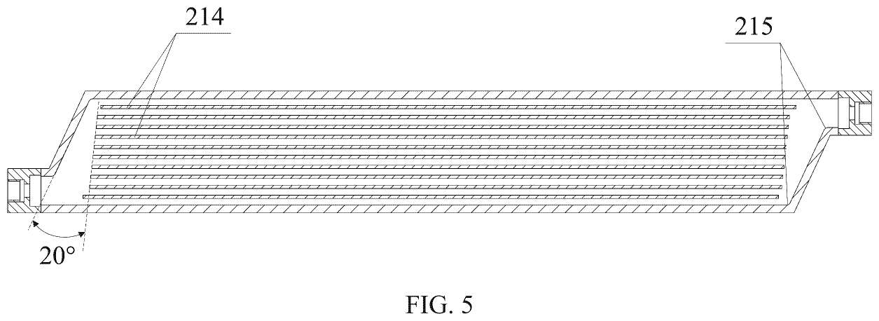

The present invention will be described in detail hereinafter with reference to the accompanying drawings as shown in FIG. 1 to FIG. 6.

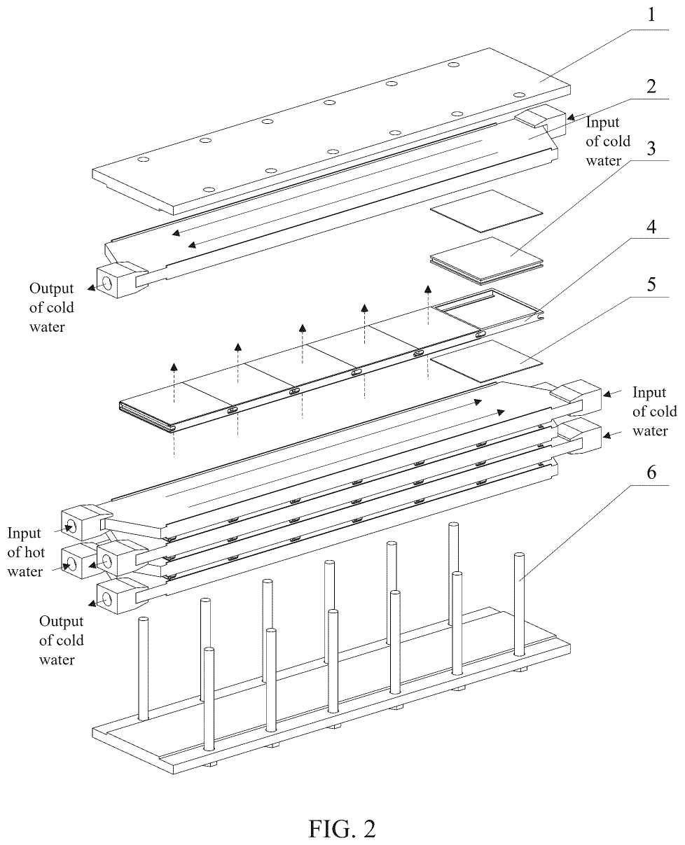

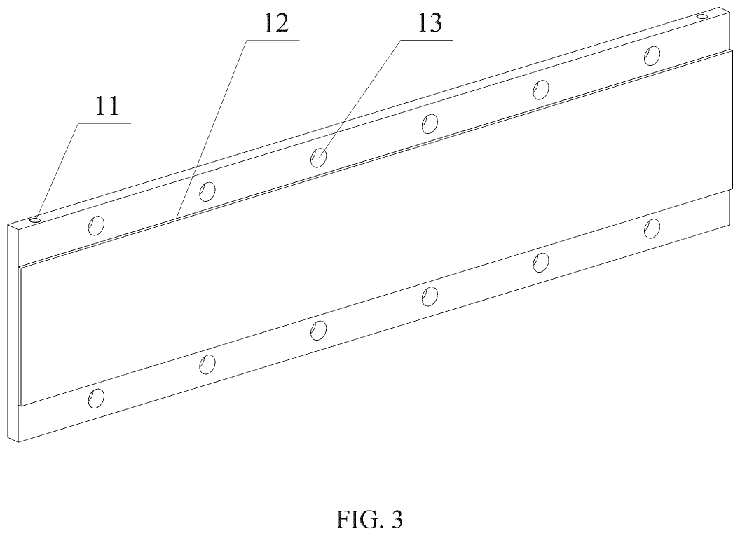

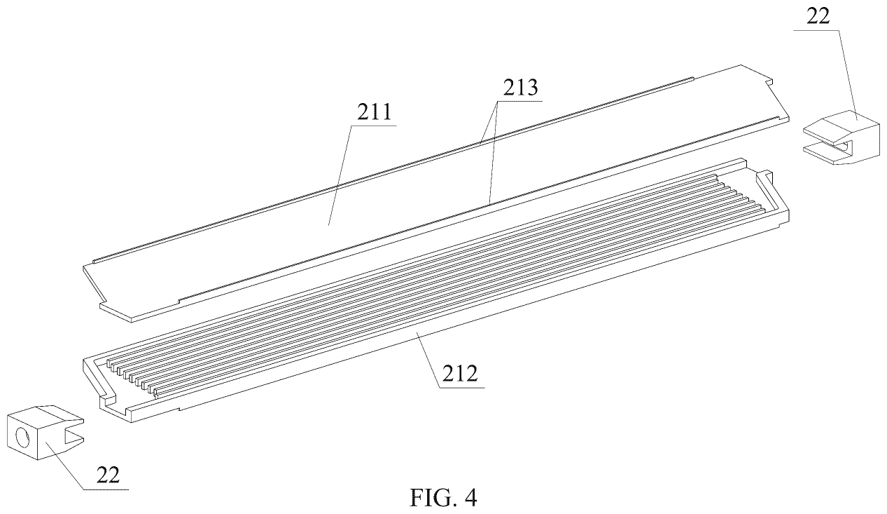

With reference to FIG. 1, FIG. 2, FIG. 3 and FIG. 4, in embodiments: a geothermal thermoelectric power generation module comprises: a fixing clamp, wherein a plurality of hot heat exchangers and a plurality of cold heat exchangers are arranged in the fixing clamp, the hot heat exchangers and the cold heat exchangers are oppositely arranged, a plurality of thermoelectric modules 3 are arranged between the hot heat exchangers and the cold heat exchangers, and two ends of the hot heat exchanger are respectively provided with a hot water input interface 22 and a hot water output interface 22; and two ends of the cold heat exchanger are respectively provided with a cold water input interface 22 and a cold water output interface 22, and the thermoelectric module 3 is connected with a wire and outputs electric energy to the outside.

According to the technical solution, a Seebeck effect is used to generate electricity, and by forming a temperature difference between two sides of the thermoelectric module 3, an electric potential difference is formed between the two sides of the thermoelectric module 3; and the formed electric potential difference may output electric energy to the outside. According to the technical solution, the thermoelectric power generation module is miniaturized and unitized; the cold heat exchanger is connected with an external cold water supply system through the cold water input interface 22 and the cold water output interface 22, so that cold water flows inside the cold heat exchanger, and the cold heat exchanger is at a low temperature, thereby keeping a side surface of the thermoelectric module 3 abutting against the cold heat exchanger at a low temperature; the hot heat exchanger is connected with an external hot water supply system through the hot water input interface 22 and the hot water output interface 22, so that hot water flows inside the hot heat exchanger, and the hot heat exchanger is at a high temperature, thereby keeping a side surface of the thermoelectric module 3 abutting against the hot heat exchanger at a high temperature; and a high temperature difference is formed between the two sides of the thermoelectric module 3, a high electric potential difference is generated, and the electric energy is output to the outside through a wire. The hot water may be geothermal-heated hot water, and the cold water may be river water, etc.; and the hot water and the cold water are pumped into a corresponding heat exchanger 2 by a water pump.

Further, a number of the cold heat exchangers is N, and one hot heat exchanger is arranged between two adjacent cold heat exchangers; and N is a natural number greater than 1.

During geothermal thermoelectric power generation, geothermal heat energy is consumed; if the hot heat exchanger is arranged on an outer side, an outer side of the hot heat exchanger may also dissipate heat to the outside, and this part of energy is wasted; and meanwhile, a working temperature of a geothermal thermoelectric power generator can also be increased, which is not conducive to the overall work. Therefore, according to the technical solution, the cold heat exchangers are arranged on two sides of the hot heat exchanger, and the two sides of the hot heat exchanger are both provided with the thermoelectric power generation module to absorb heat energy of the hot heat exchanger, thereby improving a utilization rate of the heat energy. Secondly, the cold heat exchanger is arranged on an outer side the geothermal thermoelectric power generation module, which can play a role of temperature reduction, thereby controlling a working stability of the geothermal thermoelectric power generator. During specific implementation, N=2, 3, 4, 5, etc. Preferably, N=3.

Further, a plurality of accommodating spaces for accommodating the thermoelectric modules 3 are formed between all the cold heat exchangers and the hot heat exchangers, the accommodating space is provided with a main-sequencing thermoelectric module group or a secondary-sequencing thermoelectric module group, and the main-sequencing thermoelectric module group and the secondary-sequencing thermoelectric module group are staggered; and electrode directions of the thermoelectric modules in the main-sequencing thermoelectric module group and the secondary-sequencing thermoelectric module group are opposite;
all the thermoelectric modules in the main-sequencing thermoelectric module group are connected in series through a wire to form a main primary thermoelectric module group, and all the main primary thermoelectric module groups are connected in parallel to form a main intermediate thermoelectric module group;
all the thermoelectric modules in the secondary-sequencing thermoelectric module group are connected in series through a wire to form a secondary primary thermoelectric module group, and all the secondary primary thermoelectric module groups are connected in parallel to form a secondary intermediate thermoelectric module group; and
the main intermediate thermoelectric module group and the secondary intermediate thermoelectric module group are connected in series.

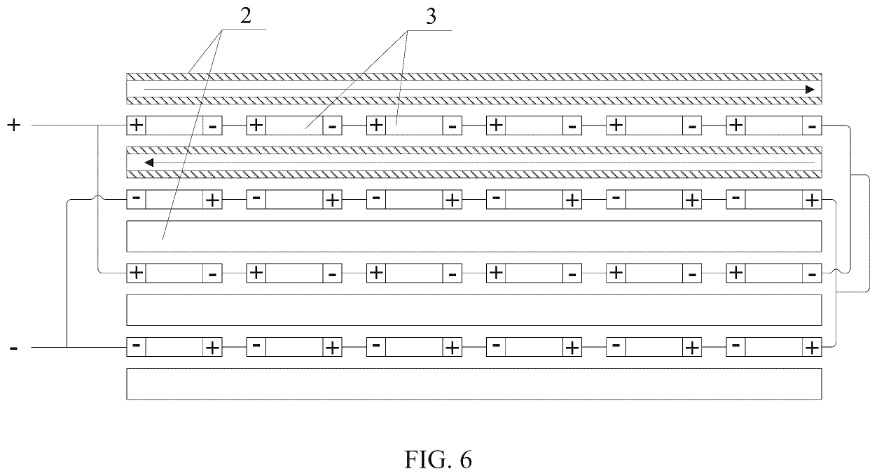

During implementation, the plurality of thermoelectric modules 3 are arranged between the hot heat exchanger and the cold heat exchanger. In order to facilitate supplying power to the outside, each thermoelectric module 3 in the accommodating space keeps consistent structure and electrode direction, and positive and negative electrodes of the thermoelectric modules 3 are connected through a wire to form a series structure. As shown in FIG. 6, main-sequencing thermoelectric modules in first and third layers are connected in series to form a main primary thermoelectric module, and secondary-sequencing thermoelectric modules in second and fourth layers are connected in series to form a secondary primary thermoelectric module; and the secondary primary thermoelectric module and the main primary thermoelectric module are connected in series, and supply power to the outside.

Advantages of the connection mode are as follows: firstly, due to heat consumption in the power generation process, a water temperature can be reduced along a flow direction of the hot water and increased along a flow direction of the cold water. Therefore, if a number of thermoelectric modules arranged in the first layer is too large, power generation efficiency of the thermoelectric module close to an outlet of the hot heat exchanger can be reduced. Under a design flow rate, a small number of (such as 5, 6 and 7) thermoelectric modules are arranged in a single layer, which can not only meet a requirement that temperature reduction of the hot water along the flow direction is not obvious, but also make an overall length of a power generation module suitable for assembly and application, thereby being a preferred solution. Secondly, the thermoelectric modules in the single layer are connected in series, which can maximize power generation power of each thermoelectric module. This is because there is still a Peltier effect in a loop during working of the thermoelectric module, which may lead to an interaction between parallel modules and eventually tend to a module with lowest power generation efficiency. All the modules are connected in series, which may lead to a failure of the power generation module once a certain module is damaged. Therefore, 4 layers of modules are connected in series and parallel, which ensures that, when one power generation module fails, only one layer of thermoelectric modules in the power generation module cannot work at most, and the remaining power generation modules may all run normally. Therefore, a reliability of the power generation module is guaranteed to the greatest extent, and the electrical connection mode is simplified at the same time, which facilitates assembly of the power generation module.

Preferably, N=2K+1, and K is a natural number. In order to make a power generation network stable, a number of main primary thermoelectric module groups is equal to a number of secondary primary thermoelectric module groups. Further preferably, K=1.

Further, a fixing bracket 4 for fixing the thermoelectric module 3 is arranged between the hot heat exchanger and the cold heat exchanger, the thermoelectric module 3 is fixed on the fixing bracket 4, and two sides of the thermoelectric module 3 are respectively provided with a flexible heat-conducting silicone sheet 5.

Due to limited flatness of surfaces of the hot heat exchanger, the cold heat exchanger and the thermoelectric module during manufacturing, when the thermoelectric module is abutted against the hot heat exchanger and the cold heat exchanger, the side surface of the thermoelectric module is not completely attached to the surfaces of the hot heat exchanger and the cold heat exchanger, and there is a gap therebetween, which leads to large thermal resistance; and after the flexible heat-conducting silicone sheet 5 is arranged, a surface of the heat-conducting silicone is completely abutted against the surface of the thermoelectric module and the surface of the hot heat exchanger or the cold heat exchanger by clamping of the fixing clamp, which can reduce the thermal resistance and achieve rapid heat transfer. Secondly, in a working process, there are a hot flow medium and a cold flow medium flowing through both of the hot heat exchanger and the cold heat exchanger. The hot heat exchanger and the cold heat exchanger are both made of metal, a temperature is gradually increased or reduced in a length direction, a change degree of thermal expansion and contraction of the hot heat exchanger and the cold heat exchanger is linear, and if the hot heat exchanger and the cold heat exchanger directly make contact with the thermoelectric module 3, there may be an uneven stress on the thermoelectric module 3, which affects a power generation stability. The flexible heat-conducting silicone sheet 5 is adopted, the silicone sheet has a relatively small degree of thermal expansion and contraction and a flexibility, and a clamping force on the thermoelectric module 3 is approximately balanced, thereby ensuring stable working of the thermoelectric module.

Further, the fixing clamp comprises two clamping plates 1, a clamping space is formed between the two clamping plates 1, the clamping plate 1 is provided with a plurality of connecting holes 13, and the two clamping plates 1 are connected by connecting pieces 6 penetrating through the connecting holes 13; and the connecting hole 13 is located in a center position of the thermoelectric module 3 in a length direction.

The connecting piece 6 may be a bolt, etc. When the two clamping plates 1 are clamped by the bolts, the connecting hole 13 is located in the center position of the thermoelectric module 3 in the length direction, so that a stress point of the clamping plate 1 is opposite to the center position of the thermoelectric module 3. Therefore, an acting force of the clamping plate 1 on the thermoelectric module 3 is approximately uniform, which improves the stability of the thermoelectric module 3.

Further, the hot water input interface 22 of the hot heat exchanger is located on the same side as the cold water output interface 22 of the cold heat exchanger, the hot water output interface 22 of the hot heat exchanger is located on the same side as the cold water input interface 22 of the cold heat exchanger, and a hot water flow direction of the hot heat exchanger is opposite to a cold water flow direction of the cold heat exchanger.

The hot water flow direction in the hot heat exchanger is designed to be opposite to the cold water flow direction in the cold heat exchanger, so that a temperature difference between the two sides of the thermoelectric module 3 is approximately equal, working conditions of all the thermoelectric modules 3 are approximately the same, and the whole thermoelectric power generation module works stably.

Further, the hot heat exchanger and the cold heat exchanger are both a heat exchanger 2, a side surface of the heat exchanger 2 connected with the thermoelectric module 3 is provided with two limiting protrusions 213 arranged in parallel, and an accommodating space matched with the fixing bracket 4 is formed between the limiting protrusions 213.

The heat exchanger 2 is provided with the limiting protrusions 213 for positioning the fixing bracket 4, which can avoid the fixing bracket 4 from shaking.

Further, a middle part of a side surface of the clamping plate 1 is provided with a boss 12, and when the clamping plate 1 and the heat exchanger 2 are clamped, the boss 12 is inserted into an accommodating space between two limiting protrusions 213.

The clamping plate 1 is provided with the boss 12, which may be better assembled with the heat exchanger 2 when clamped with the heat exchanger 2, so as to prevent the heat exchanger 2 from sliding relatively.

Further, the heat exchanger comprises a bottom shell 212 and an end cover 211, two sides of the bottom shell 212 are respectively provided with an inlet and an outlet, and the inlet and the outlet are respectively located at a lower end and an upper end of the bottom shell 212; and a middle part of the bottom shell 212 is provided with a plurality of reinforcing ribs 214, and the reinforcing ribs 214 divide an internal space of the heat exchanger into a plurality of channels.

The inlet and the outlet are respectively connected with the hot water input interface 22 and the hot water output interface 22, or the cold water input interface 22 and the cold water output interface 22. The reinforcing ribs 214 are provided, so that when the liquid flows in the bottom shell 212, a turbulent flow is reduced, and a fluid flow rate is evenly distributed in each channel. Secondly, the reinforcing ribs 214 may also reinforce the structure of the heat exchanger. A temperature of the heat exchanger in a length direction is gradually increased or reduced, the heat exchanger is generally made of metal, and has different thermal expansion and contraction dimensions, which is easy to cause a large internal stress formed in the interior, so as to cause deformations of the bottom shell 212 and the end cover 211, thereby affecting thermal contact with the thermoelectric module. After the reinforcing ribs 214 are added, an overall strength is improved, which can reduce or avoid the deformations.

Further, side plates on the two sides of the bottom shell 212 are obliquely arranged, so that a water pressure difference between two sides of the channel is within a predetermined range.

In order to make the thermoelectric power generation module work stably, the heat exchanger 2 needs to keep approximately consistent temperature in a width direction, and the heat exchanger 2 also keeps consistent temperature change trend in the length direction. Therefore, the liquid needs to keep approximately balanced flowing in the heat exchanger, especially in the width direction. Therefore, the side plates on the two sides of the shell are obliquely arranged to adjust the water pressure difference between the two sides of the channel, so that the water pressure difference between two ends of each channel is equal or approximately equal, thereby making a flow velocity of the liquid in each channel equal or approximately equal, and keeping approximately consistent heat exchange between the liquid and the heat exchanger 2 in the width direction. Secondly, this consistency also makes a temperature difference between the heat exchangers 2 on the two sides of the thermoelectric module 3 in the length direction equal or approximately equal, and within a predetermined range, although a temperature of each side of the thermoelectric module 3 in the length direction is changing, the temperature difference is unchanged or within a certain range, so that the thermoelectric module 3 works more stably.

Preferably, an angle of inclination of the side plate is 10 degrees to 40 degrees.

The angle of inclination of the side plates on two sides may be adjusted according to a test. The angle of inclination ranges from 10 degrees to 40 degrees, and is especially 15 degrees, 20 degrees, 25 degrees, etc.

Further, a width of the channel is gradually increased from the outside to the inside.

According to fluid dynamics analysis, there is a larger turbulent flow in a position closer to a port, so that a smaller width needs to be designed for the channel; while there is a smaller turbulent flow in a position far away from the port, and because the inlet and the outlet are arranged at the upper and lower ends, the width of the channel may be changed to reduce the reinforcing ribs 214.

Further, an upper edge of the clamping plate 1 is provided with a threaded hole.

The upper edge of the clamping plate 11 is designed with two M4 threaded holes 11. In practical application, M4 bolts are screwed into the threaded holes 11 in advance, and after the thermoelectric power generation module is put in a predetermined position, the M4 bolts are unscrewed, and upper surfaces of the bolts and a lower edge of the clamping plate 11 are fixed in the fixing bracket by reversely utilizing pre-tightening forces of the bolts.

Preferably, fluid turns are all designed with a transition fillet 215.

A geothermal thermoelectric power generator comprises a plurality of geothermal thermoelectric power generation modules above, and further comprises a hot water supply system and a cold water supply system, wherein the cold water supply system is connected with the cold heat exchanger, and the hot water supply system is connected with the hot heat exchanger.

The above contents are only preferred embodiments of the present invention. According to the idea of the present invention, there will be some changes in the concrete implementation and application scope for those of ordinary skills in the art, and the contents of the specification should not be construed as limitations to the present invention.

We claim:

1. A geothermal thermoelectric power generation module, comprising: a fixing clamp, wherein a plurality of hot heat exchangers and a plurality of cold heat exchangers are arranged in the fixing clamp, the hot heat exchangers and the cold heat exchangers are oppositely arranged, a plurality of thermoelectric modules are arranged between the hot heat exchangers and the cold heat exchangers, and two ends of the hot heat exchanger are respectively provided with a hot water input interface and a hot water output interface; and two ends of the cold heat exchanger are respectively provided with a cold water input interface and a cold water output interface, and the thermoelectric module is connected with a wire and outputs electric energy to the outside;
a number of the cold heat exchangers is N, and one hot heat exchanger is arranged between two adjacent cold heat exchangers; and N is a natural number greater than 1;
N=2K+1, and K is a natural number; a plurality of accommodating spaces for accommodating the thermoelectric modules are formed between all the cold heat exchangers and the hot heat exchangers, the accommodating space is provided with a main-sequencing thermoelectric module group or a secondary-sequencing thermoelectric module group, and the main-sequencing thermoelectric module group and the secondary-sequencing thermoelectric module group are staggered; and electrode directions of the thermoelectric modules in the main-sequencing thermoelectric module group and the secondary-sequencing thermoelectric module group are opposite;
all the thermoelectric modules in the main-sequencing thermoelectric module group are connected in series through a wire to form a main primary thermoelectric module group, and all the main primary thermoelectric module groups are connected in parallel to form a main intermediate thermoelectric module group;
all the thermoelectric modules in the secondary-sequencing thermoelectric module group are connected in series through a wire to form a secondary primary thermoelectric module group, and all the secondary primary thermoelectric module groups are connected in parallel to form a secondary intermediate thermoelectric module group;
the main intermediate thermoelectric module group and the secondary intermediate thermoelectric module group are connected in series; and
a fixing bracket for fixing the thermoelectric module is arranged between the hot heat exchanger and the cold heat exchanger, the thermoelectric module is fixed on the fixing bracket, and two sides of the thermoelectric module are respectively provided with a flexible heat-conducting silicone sheet.

2. The geothermal thermoelectric power generation module according to claim 1, wherein the fixing clamp comprises two clamping plates, a clamping space is formed between the two clamping plates, the clamping plate is provided with a plurality of connecting holes, and the two clamping plates are connected by connecting pieces penetrating through the connecting holes; and the connecting hole is located in a center position of the thermoelectric module in a length direction.

3. The geothermal thermoelectric power generation module according to claim 1, wherein the hot water input interface of the hot heat exchanger is located on the same side as the cold water output interface of the cold heat exchanger, the hot water output interface of the hot heat exchanger is located on the same side as the cold water input interface of the cold heat exchanger, and a hot water flow direction of the hot heat exchanger is opposite to a cold water flow direction of the cold heat exchanger.

4. The geothermal thermoelectric power generation module according to claim 1, wherein the hot heat exchanger and the cold heat exchanger are both a heat exchanger, a side surface of the heat exchanger connected with the thermoelectric module is provided with two limiting protrusions arranged in parallel, and an accommodating space matched with the fixing bracket is formed between the limiting protrusions.

5. The geothermal thermoelectric power generation module according to claim 2, wherein a middle part of a side surface of the clamping plate is provided with a boss, and when the clamping plate is clamped with the heat exchanger, the boss is inserted into an accommodating space between two limiting protrusions.

6. The geothermal thermoelectric power generation module according to claim 3, wherein the heat exchanger comprises a bottom shell and an end cover, two sides of the bottom shell are respectively provided with an inlet and an outlet, and the inlet and the outlet are respectively located at a lower end and an upper end of the bottom shell; a middle part of the bottom shell is provided with a plurality of reinforcing ribs, and the reinforcing ribs divide an internal space of the heat exchanger into a plurality of channels; and side plates on the two sides of the bottom shell are obliquely arranged, so that a water pressure difference between two sides of the channel is equal or within a predetermined range.

7. A geothermal thermoelectric power generator, comprising the geothermal thermoelectric power generation module according to claim 1, and further comprising a hot water supply system and a cold water supply system, wherein the cold water supply system is connected with the cold heat exchanger, and the hot water supply system is connected with the hot heat exchanger.
